(19) United States
(12) Patent Application Publication
(10) Pub. No.: US 2025/0218956 A1
(43) Pub. Date: Jul. 3, 2025

(54) METHODS AND APPARATUS FOR MOUNTING SEMICONDUCTOR DEVICES IN CAVITIES

(71) Applicant: Intel Corporation, Santa Clara, CA (US)

(72) Inventors: Shayan Kaviani, Phoenix, AZ (US); Ehsan Zamani, Phoenix, AZ (US); Mahdi Mohammadighaleni, Phoenix, AZ (US); Darko Grujicic, Chandler, AZ (US); Rengarajan Shanmugam, Tempe, AZ (US); Elham Tavakoli, Phoenix, AZ (US); Kihyun Kim, Chandler, AZ (US); Srinivas Pietambaram, Chandler, AZ (US)

(21) Appl. No.: 18/398,620

(22) Filed: Dec. 28, 2023

(51) Int. Cl. H01L 23/538; H01L 21/48; H01L 23/00; H01L 23/64

(52) U.S. Cl. CPC H01L 23/5386; H01L 21/4846; H01L 23/642; H01L 24/16; H01L 2224/16227

(57) ABSTRACT

Methods and apparatus for mounting semiconductor devices in cavities are disclosed herein. An example semiconductor package includes a package substrate core having a cavity positioned therein; a pedestal positioned within the cavity of the core, the pedestal including a conductive material; and a capacitor disposed within the cavity, the capacitor positioned on the pedestal.

### FIELD OF THE DISCLOSURE

This disclosure relates generally to semiconductor packages and, more particularly, to methods and apparatus for mounting semiconductor devices in cavities.

### BACKGROUND

In many electronic devices, integrated circuit (IC) chips and/or semiconductor dies are connected to larger circuit boards such as motherboards and/or other types of printed circuit boards (PCBs) via a package substrate. Some known integrated circuit (IC) packages utilize voltage regulators for power delivery applications. In some instances, capacitors and/or other semiconductor devices used for such voltage regulators can be included in the package substrate of an IC package.

### BRIEF DESCRIPTION OF THE DRAWINGS

FIG. 1 is a cross-sectional side view of an integrated circuit (IC) package constructed in accordance with teachings disclosed herein

FIG. 2 is a cross-sectional side view of an example IC device including an example pedestal constructed in accordance with teachings disclosed herein.

FIGS. 3A-3I illustrate various stages of manufacture of the example pedestal of FIG. 2.

FIG. 4 is a cross-sectional side view of another example IC device including example pedestals in accordance with teachings disclosed herein.

FIG. 5 is a flowchart representative of an example method of fabricating the example pedestal(s) of FIGS. 3A-3I and/or FIG. 4.

FIG. 6 is a top view of a wafer including dies that may be included in an IC package constructed in accordance with teachings disclosed herein.

FIG. 7 is a cross-sectional side view of an IC device that may be included in an IC package constructed in accordance with teachings disclosed herein.

FIG. 8 is a cross-sectional side view of an IC device assembly that may include an IC package constructed in accordance with teachings disclosed herein.

FIG. 9 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

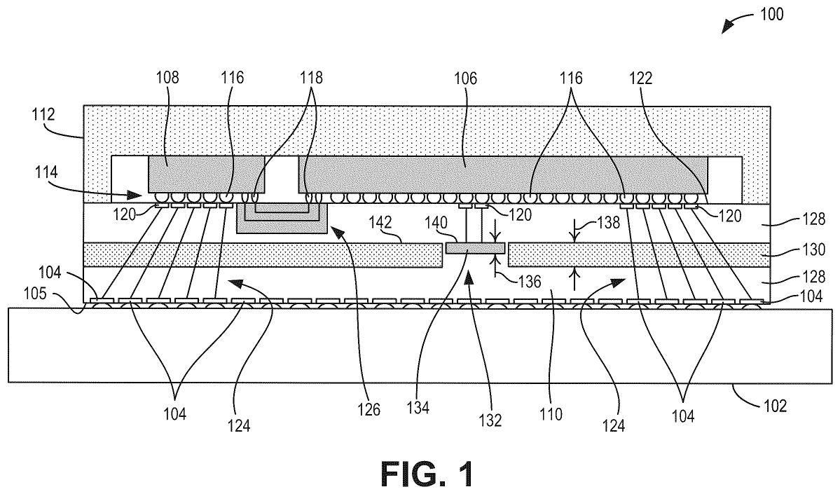

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a core 130 the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In other examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and does not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plain view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

As shown in the illustrated example, the substrate core 130 includes a cavity 132 in which a semiconductor device 134 is embedded. In some examples, the semiconductor device 134 is positioned on a pedestal, a spacer, or other support structure within the cavity 132 as discussed further herein. In some examples, the semiconductor device 134 is a passive semiconductor die (e.g., a die that does not include transistors). In this example, the semiconductor device 134 is a deep trench capacitor die (also referred to herein as a deep trench capacitor, or simply capacitor, for short). In some such examples, the deep trench capacitor is used to enable efficient power delivery to a fully integrated voltage regulator within the first die 106 in the IC package 100. In other examples, other types of semiconductor devices can be embedded within the cavity 132 of the substrate core 130 in addition to or instead of a deep trench capacitor. In some examples, more than one semiconductor device 134 can be embedded within the cavity 132 of the substrate core 130. In some examples, the substrate core 130 can include multiple cavities each containing one or more separate semiconductor devices 134.

As noted above, in this example, the semiconductor device 134 is a deep trench capacitor and will be referred to as such going forward. As shown in the illustrated example, the deep trench capacitor 134 is electrically coupled to the first die 106. In some examples, the deep trench capacitor 134 is positioned in close proximity to the first die 106 (e.g., within the substrate core 130 rather than spaced farther away like land-side capacitors) to reduce inductance and parasitic effects, thereby increasing the effectiveness of the deep trench capacitor 134 (and/or achieving a given capacitance with a smaller sized capacitor). However, a challenge with embedding a deep trench capacitor 134 within a core 130 of a substrate arises from the thickness mismatch between the deep trench capacitor 134 and the core 130. In this example, the deep trench capacitor 134 is constructed through wafer-level processing from a semiconductor (e.g., silicon) wafer. Due to the nature of such wafer-level processing, the deep trench capacitor 134 has a thickness 136 limited to less than or equal to approximately 800 micrometers (μm) or less (e.g., less than or equal to approximately 700 μm, less than or equal to approximately 650 μm, less than or equal to approximately 600 μm, etc.). By contrast, the substrate core 130 can be significantly thicker, especially for larger packages as noted above. For instance, in some examples, the core 130 has a thickness 138 that is at least 20% greater than the thickness 136 of the deep trench capacitor 134 or more (e.g., at least 25% greater, at least 30% greater, at least 50% greater, at least 75% greater, at least twice as great, etc.). More specifically, in some examples, the thickness 138 of the core 130 is greater than approximately 800 or more (e.g., greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). Thus, as shown in FIG. 1, the thickness 136 of the deep trench capacitor 134 is less than the thickness 138 of the core 130.

The mismatch between the thicknesses 136, 138 of the deep trench capacitor 134 and the core 130 presents challenges in positioning the deep trench capacitor 134 within the cavity 132 of the core 130. Specifically, the relatively small size of the deep trench capacitor 134 can result in misalignments in any of the x, y, and z axes and/or rotational shifting or tilting because of the difficulty in securing the deep trench capacitor in place. In particular, the use of adhesives and/or an encapsulant to hold the deep trench capacitor 134 in place can be difficult because of the large space within the cavity 132 that needs to be filled which can take time to set or cure during which the deep trench capacitor 134 may shift, rotate, or otherwise move. As a result, a contact surface 140 of the deep trench capacitor 134 (e.g., a surface containing contacts with which the deep trench capacitor 134 is electrically coupled to (and facing towards) the first die 106) may not be aligned (e.g., flush) with a corresponding surface 142 (also facing towards the first die 106) of the substrate core 130. Such misalignment can negatively affect the ability of the deep trench capacitor 134 to electrically connect with the interconnects within the build-up region 128 above the core 130. Furthermore, the non-homogeneity of materials within the cavity 132 (e.g., a deep trench capacitor 134 and a relatively large volume of adhesive and/or encapsulant) can create processing challenges downstream and/or increase risks of warpage and/or mechanical stress in the package substrate 110.

Examples disclosed herein overcome the above challenges by providing a spacer, pedestal, platform, or other structure within the cavity 132 to support the deep trench capacitor 134 at a suitable height and at a suitable location relative to the core 130. In particular, examples disclosed herein enable fabrication of a pedestal positioned inside the substrate core. Further, examples disclosed herein enable placement or positioning of a deet trench capacitor on the pedestal disclosed herein.

Disclosed examples enable control of a target height of the pedestal based on a thickness of the core substrate and a stop-point of an etch for fabricating the pedestal. Certain examples enable relatively low total thickness variation (TTV) and/or roughness of the pedestal, which can be controlled based on an etch method used to fabricate the pedestal. Disclosed examples enable more precise securing of the deep trench capacitor relative to previous techniques.

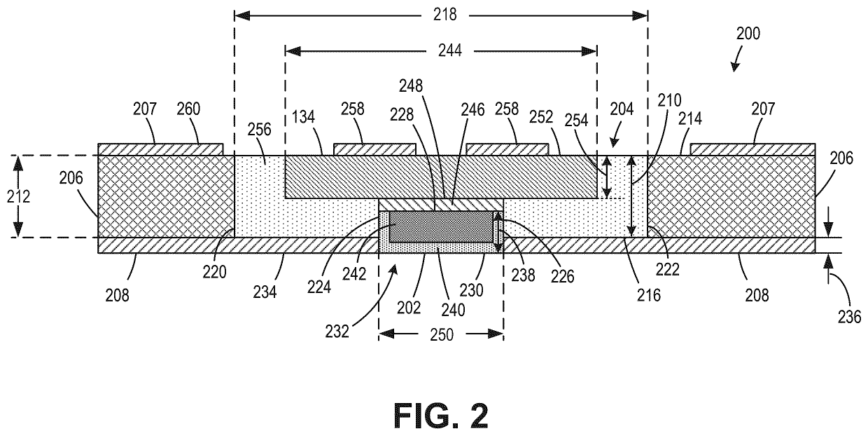

FIG. 2 is a cross-sectional side view of a portion of an example IC device 200 including an example pedestal 202 (e.g., a platform, a stage, a protrusion, a spacer, etc.) constructed in accordance with teachings of this disclosure. In particular, FIG. 2 illustrates the pedestal 202 disposed in a cavity 204 (e.g., a recess, a trench, etc.) of a substrate core 206 (e.g., a package substrate core, the core 130 of FIG. 1, etc.). While the example substrate core 206 of FIG. 2 includes one pedestal 202, in other examples, the substrate core 206 may have more than one pedestal 202 (e.g., two pedestals 202, more than two pedestals 202, more than three pedestals 202, etc.). In some examples, multiple pedestals 202 can be positioned with the same cavity 204. In some examples, multiple pedestals 202 can be distributed among multiple cavities 204, with different ones of the cavities 204 having one or more pedestals 202.

In the illustrated example FIG. 2, the substrate core 206 is an organic core that is lined with a first outer layer 207 on a first surface 214 of the substrate core 206 and with a second outer layer 208 on a second surface 216 of the substrate core 206. In some examples, the first and/or second outer layers 207, 208 208 include an electrically conductive material (e.g., a metal). For example, the first and/or second outer layers 207, 208 can include copper, gold, aluminum and/or any other electrically conductive material(s). In some examples, the first and/or second outer layers 207, 208 are attached to the substrate core 206 during the fabrication of the substrate core 206. That is, in some examples, the first and/or second outer layers 207, 208 can be considered as part of the substrate core 206. In some examples, the first and/or second outer layers 207, 208 can be added later. In some such examples, the first and/or second outer layers 207, 208 replace an electrically conductive layer previously fabricated and subsequently removed from the substrate core 206. In some examples, the first and/or second outer layers 207, 208 may be omitted from the substrate core 206. In some examples, the first and/or second outer layers 207, 208 are omitted.

The cavity 204 of FIG. 2 has a depth 210 (not including the thicknesses of the outer layers 207, 208) that corresponds to a thickness 212 of the substrate core 206. In particular, the cavity 204 extends from the first surface 214 of the substrate core 206 (on which the first outer layer 207 is disposed) to the first surface 216 of the substrate core 206 (on which the second outer layer 208 is disposed). In some examples, the cavity 204 extends into at least a portion of the first outer layer 207 and/or the second outer layer 208. The cavity 204 has a width 218 that extends from a first cavity wall 220 defined by a first lateral surface of the substrate core 206 to a second cavity wall 222 defined by a second lateral surface of the substrate core 206.

As illustrated in FIG. 2, the pedestal 202 includes a first (e.g., lateral) wall 224 (e.g., surface, etc.), a second (e.g., lateral) wall 226 (e.g., surface, etc.) opposite to the first wall 224, a third (e.g., upper) wall 228 (e.g., surface, etc.) that extends between the first and second walls 224, 226, and a fourth (e.g., base) wall 230 (e.g., surface, etc.) opposite the third wall 228. In some examples, the pedestal 202 has the shape of a cylindrical pillar (e.g., with a circular cross-section in a plane parallel to the first and/or second surfaces 214, 216 of the substrate core 206). Thus, in some examples, the first and second walls 226 are a continuation of one another and correspond to the round exterior or perimeter of the pedestal 202. The pedestal 202 of FIG. 2 is positioned in an opening 232 that extends through the second outer layer 208 that defines a base wall of the cavity 204. In the illustrated example of FIG. 2, the fourth wall 230 of the pedestal 202 is substantially flush (e.g., aligned, etc.) with an exterior surface 234 of the second outer layer 208. In some examples, the fourth wall 230 of the pedestal 202 is substantially flush (e.g., aligned, etc.) with the first surface 216 of the substrate core 206. In some examples, the fourth wall 230 of the pedestal 202 is positioned between the first surface 216 of the substrate core 206 and the exterior surface 234 of the second outer layer 208. A thickness 236 of the second outer layer 208 is less than a height 238 of the pedestal 202.

The pedestal 202 of FIG. 2 includes a seed layer 240 and an electrically conductive material 242 disposed on (e.g., within) the seed layer 240. For example, the conductive material 242 can include copper, gold, aluminum and/or any other electrically conductive material(s). The walls 224, 226, 228, 230 of the pedestal 202 are defined by or include a least a portion of the seed layer 240 and/or the conductive material 242. In some examples, the conductive material 242 defines a main body of the pedestal 202. In some examples, the seed layer 240 is omitted.

In some examples, the seed layer 240 includes or is defined by a material substantially similar to or the same as the conductive material 242. In some examples, the seed layer 240 is formed of a material that is different than the conductive material 242. In other words, the pedestal 202 includes a metal extending continuously between opposing walls 224, 224 (e.g., opposing sides) of the pedestal 202.

As illustrated in FIG. 2, an example semiconductor device (e.g., the semiconductor device 134 of FIG. 1) is positioned on the pedestal 202 within the cavity 204. A width 244 of the semiconductor device 134 is less than the width 218 of the cavity 204. As noted above, in this example, the semiconductor device 134 is a deep trench capacitor and will be referred to as such going forward. However, the semiconductor device 134 can be another passive semiconductor die in other examples.

The deep trench capacitor 134 is coupled to the pedestal 202 by an adhesive 246 (e.g., an adhesive material). In particular, a first surface 248 of the deep trench capacitor 134 is coupled to the third wall 228 of the pedestal 202 by the adhesive 246. In some examples, the adhesive 246 is a die adhesion film that provides adhesion between the deep trench capacitor 134 and the pedestal 202. In other words, the adhesive 246 is disposed between the first surface 248 of the deep trench capacitor 134 and the third wall 228 of the pedestal 202 to couple the deep trench capacitor 134 to the pedestal 202.

The pedestal 202 of FIG. 2 has a diameter or width 250 that is less than the width 244 of the deep trench capacitor 134. For example, in some examples, the width 250 of the pedestal 202 is less than one fifth the width 244 of the deep trench capacitor 134. However, examples disclosed herein are not limited thereto. In other examples, the width 250 of the pedestal 202 can be larger than one fifth the width 244 of the deep trench capacitor 134. In some examples, the width 250 of the pedestal 202 is approximately less than 100 microns (e.g., less than 100 microns, less than 90 microns, less than 80 microns, etc.). In some examples, the width 244 of the deep trench capacitor 134 is approximately less than 800 microns (e.g., less than 800 microns, less than 700 microns, less than 600 microns, etc.). In some examples, the width 244 of the deep trench capacitor 134 is approximately greater than 500 microns (e.g., greater than 500 microns, greater than 700 microns, greater than 600 microns, etc.). In this example, the adhesive 246 extends across all or substantially all of the surface of the third wall 228 of the pedestal 202. However, in this example, the adhesive 246 does not appreciably extend beyond the outer (first and second) walls 224, 226 of the pedestal 202. That is, the width of the adhesive 246 substantially equal to the width 250 of the pedestal. As such, the adhesive 246 covers less than all of the first surface 248 of the deep trench capacitor 134. In other examples, the adhesive 246 can cover all or substantially all of the first surface 248 of the deep trench capacitor 134.

In the illustrated example of FIG. 2, a second surface 252 of the deep trench capacitor 134 that is opposite the first surface 248 of the deep trench capacitor 134 is substantially flush with the first surface 214 of the substrate core 206. The thickness 212 of the substrate core 206 is larger than a thickness 254 of the deep trench capacitor 134. In other words, the deep trench capacitor 134 is embedded in the cavity 204 of the substrate core 206. In some examples, the depth 210 of the cavity 204 corresponds to the height 238 of the pedestal 202 and the thickness 254 of the deep trench capacitor 134. In other words, the depth 210 of the cavity 204 is at least partially based on the height 238 of the pedestal 202 and the thickness 254 of the deep trench capacitor 134. For example, the depth 210 of the cavity 204 can be such that the deep trench capacitor 134 is embedded in the cavity 204 as the deep trench capacitor 134 is positioned on the pedestal 202. In other examples, the deep trench capacitor 134 can be positioned on the pedestal 202 such that the second surface 252 of the deep trench capacitor 134 is substantially flush with an exterior surface 260 of the first outer layer 207.

In this example, the deep trench capacitor 134 includes contact pads 258 that protrude outward from the second surface 252 of the deep trench capacitor 134. Further, in this example, the outer surfaces of the contact pads 258 are substantially flush (e.g., aligned, etc.) with the exterior surface of the first outer layer 207. In some examples, the contact pads 258 and the first outer layer 207 are fabricated during a same process to produce the substantial alignment. In some examples, the contact pads 258 may be embedded within and substantially flush with the second surface 252 of the deep trench capacitor 134. In some such examples, the height 238 of the pedestal 202 may be adjusted so that the second surface 252 of the deep trench capacitor 134 is substantially flush with the exterior surface 260 of the first outer layer 207.

As illustrated in FIG. 2, a mold material 256 is positioned to fill the cavity 204. In particular, the mold material 256 fills the cavity 204 and covers exposed surfaces within the cavity 204 including the inner surface of the second outer layer 208, exposed surfaces of the pedestal 202, exposed surfaces of the adhesive 246, exposed surfaces of the deep trench capacitor 134, and the exposed first and second cavity walls 220, 222. Stated differently, the mold material 256 is deposited into open areas of the cavity 204 to fill in the space or gaps within the cavity 204 and surround and/or enclose the deep trench capacitor 134 and the pedestal 202. The mold material 256 is structured to secure (e.g., fix, maintain, etc.) the deep trench capacitor 134 inside the cavity 204. In some examples, the mold material 256 is a liquid polymer that has been cured, but the mold material 256 can be another type of mold material in other examples.

The pedestal 202, which includes the conductive material 242, has more rigidity relative to the mold material (at least prior to being cured). As such, the pedestal 202 can be relied on to support the deep trench capacitor 134 in place (e.g., in alignment with the first surface 214 of the substrate core 206) while the mold material is applied and subsequently cured. In other words, the pedestal 202 is a rigid platform on which the deep trench capacitor 134 can be assembled. As such, the pedestal 202 provides for more precise securing of the deep trench capacitor 134 in the cavity 204.

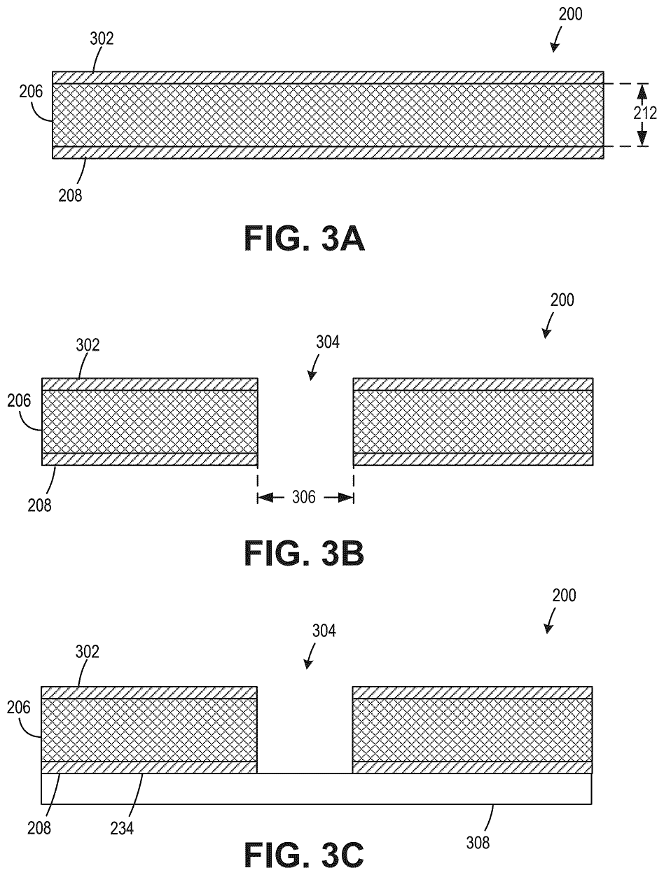

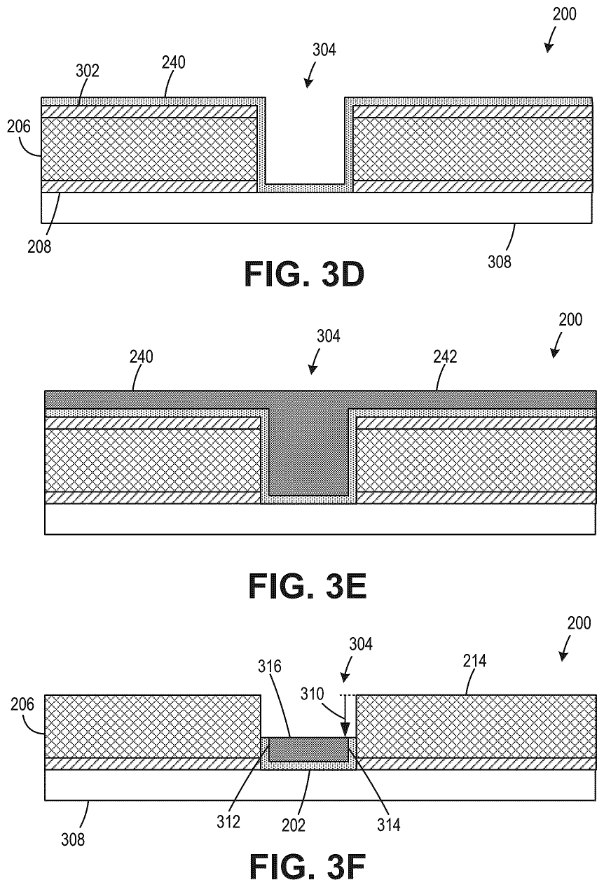

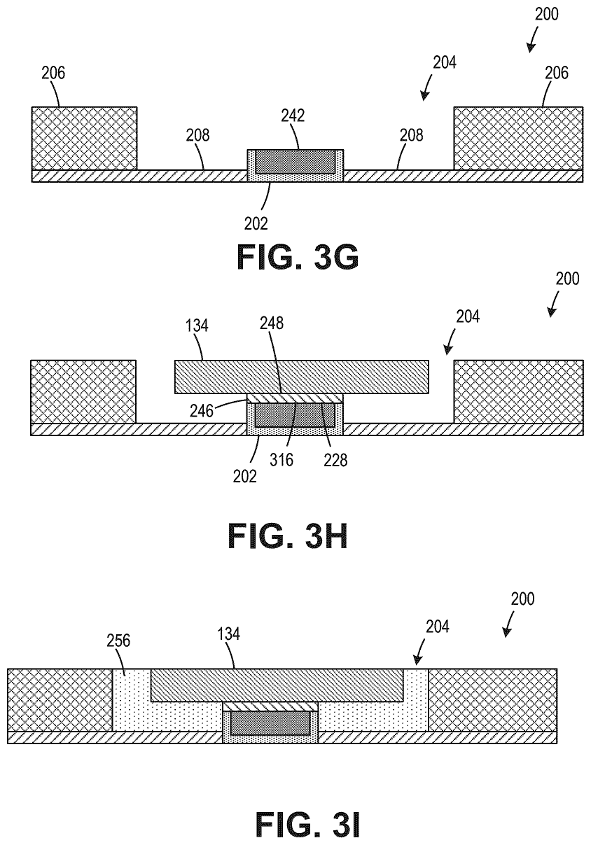

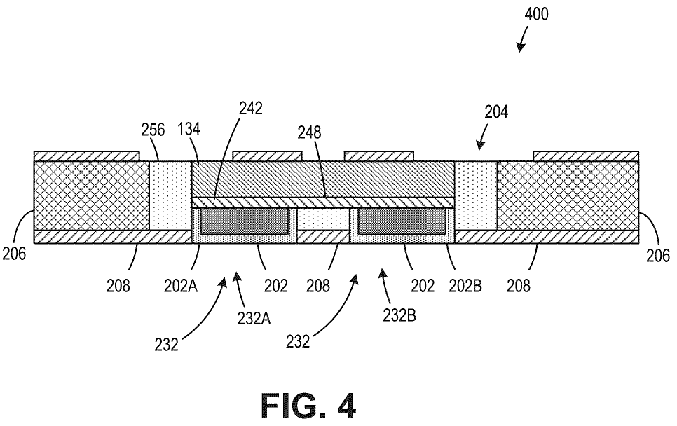

FIGS. 3A-3I illustrate various stages of manufacture of an example pedestal 202 disclosed herein. In particular, FIGS. 3A-3I illustrate an example method to manufacture an example IC device (e.g., the IC device 200 of FIG. 2, the IC device 400 of FIG. 4, and/or any other structure having a pedestal 202 disclosed herein). For example, FIGS. 3A-3I are cross-sectional illustrations of the example IC device 200 of FIG. 2 at various manufacturing stages. For purposes of explanation, FIGS. 3A-3I have been simplified to produce an IC device 200 with only one pedestal 202 in one cavity 204. However, any suitable number of pedestals 202 and/or any suitable number of cavities 204 may be implemented.

Turning in detail to the drawings, FIG. 3A illustrates the substrate core 206 of the IC device 200. In the illustrated example of FIG. 3A, the substrate core 206 includes the second outer layer 208 and a different outer layer 302. In this example, the different outer layer 302 is different than the first outer layer 207 discussed above because, as detailed below, the different outer layer 302 is to be removed and replaced with the first outer layer 207 at a later stage in the manufacturing process. However, in other examples, the different outer layer 302 can correspond to the first outer layer 208 that is retained throughout the manufacturing process. In some examples, the outer layers 208, 302 are electrically conductive layers. In some examples, the second outer layer 208 and/or the different outer layer 302 are omitted.

The thickness 212 of the substrate core 206 (not including the thicknesses of the outer layers 208, 302) can be based on the amount of structural support to be provided by the substrate core 206 within the package substrate of an associated IC package (e.g., the IC package 100 of FIG. 1). For instance, IC packages with relatively large footprints usually need a stronger package substrate and, thus, a thicker package substrate core. As indicated above, in some examples, the thickness 212 of the core 206 is greater than approximately 800 μm or more (e.g., greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). However, the thickness 212 of the substrate core 206 can be smaller than 800 μm in other examples.

FIG. 3B illustrates the IC device 200 with an opening 304 extending through the outer layers 208, 302 and the substrate core 206. The opening 304 corresponds to the opening 232 that extends through the base wall of the cavity 204 (e.g., the second outer layer 208) illustrated in FIG. 2. The opening 304 has a diameter 306 that corresponds to a target diameter or width 250 of the pedestal 202 (FIG. 2). In some examples, the opening 304 is fabricating using the same or similar process to fabricate plated through-holes in the substrate core 206 and, thus, is similarly dimensioned. In some examples, the opening 304 has a diameter 306 of approximately less than 100 microns (e.g., less than 100 microns, less than 90 microns, less than 80 microns, less than 60 microns, less than 45 microns, etc.). In some examples, the opening 304 has a diameter 306 between approximately 45 microns and 50 microns. Formation of the opening 304 can be achieved by any appropriate process including, but not limited to, drilling (e.g., mechanical and/or laser drilling and subsequent cleaning), etching, chemical and/or mechanical polishing, and/or any other via manufacturing techniques and/or any other semiconductor manufacturing process(es).

FIG. 3C illustrates the IC device 200 after attachment of a carrier 308 (e.g., a film, a carrier film, etc.) to a first side of the substrate core 206. In particular, in the illustrated example of FIG. 3C, the carrier 308 is attached to the exterior surface 234 of the second outer layer 208. The carrier 308 is a temporary carrier to facilitate development or formation of the pedestal 202 (FIG. 2). For example, the carrier 308 can be another substrate (e.g., a glass substrate, etc.) or another film. The carrier 308 can be attached via any suitable attachment technique, such as via a molding material, an epoxy, an adhesive, etc.

FIG. 3D illustrates the IC device 200 after deposition of the seed layer 240. The seed layer 240 is deposited on exposed surfaces of the substrate core 206 (e.g., exposed surfaces of the outer layers 208, 302 and the substrate core 206) and exposed surfaces of the carrier 308. For example, a seed material can be deposited across the IC device 200 to provide the seed layer 240. The seed layer 240 can be deposited using suitable deposition techniques for IC devices (e.g., electroless plating).

FIG. 3E illustrates the IC device 200 after deposition of the electrically conductive material 242. In particular, the conductive material 242 is deposited to fill the opening 304. The conductive material 242 can be deposited using any suitable deposition techniques for IC devices (e.g., electrolytic plating).

FIG. 3F illustrates the IC device 200 after formation of the pedestal 202. As illustrated in FIG. 3F, the pedestal 202 at this stage is positioned on the carrier 308 in the opening 304. The pedestal 202 is fabricated by removing portions of the conductive material 242 and the seed layer 240 in the opening 304 down to a target depth 310. In particular, the target depth 310 corresponds to a target height of the pedestal 202 (e.g., the height 238 of FIG. 1). As discussed above, the pedestal height 238 (FIG. 2) is based on the thickness 212 of the substrate core 206 and the thickness 254 of the deep trench capacitor 134 (FIG. 2).

Further, in the illustrated example of FIG. 3F, portions of the conductive material 242 and the seed layer 240 are removed from the first surface 214 of the substrate core 206. In this example, the different outer layer 302 is also removed. The portions of the conductive material 242 and the seed layer 240, as well as the different outer layer 302, can be removed using any suitable removal process for semiconductor devices. For example, the portions of the conductive material 242, the seed layer 240, and the different outer layer 302 can be removed via etching (e.g., flash etching, bulk etching, etc.). In other examples, the portions of the conductive material 242, the seed layer 240, and the different outer layer 302 can be removed via any other suitable material removal process.

After removal of the portions of the conductive material 242 and the seed layer 240, the pedestal 202 is defined. As illustrated, the seed layer 240 of FIG. 3F is disposed on lateral walls 312, 314 of the conductive material 242. As noted above, the conductive material 242 can define a main body of the pedestal 202. A surface 316 of the conductive material 242 remains exposed (e.g., devoid of the seed layer 240) to be coupled to the deep trench capacitor 134 as discussed in further detail below.

FIG. 3G illustrates the IC device 200 after removal of the carrier 308 and formation of the cavity 204. In particular, the cavity 204 is to surround the pedestal 202. In some examples, the cavity 204 is formed by a drilling process or technique. In some examples, the presence of a conductive material can be used at a stop point for a laser drilling process. For example, the drilling process can be applied to the substrate core 206 in a loop until detection of a conductive material (e.g., the second outer layer 208 and/or the conductive material 242 of the pedestal 202).

FIG. 3H illustrates the IC device 200 after assembly of the deep trench capacitor 134 on the pedestal 202, which acts as a rigid platform. In particular, after formation of the cavity 204, the substrate core 206 has sufficient space in which to mount the deep trench capacitor 134 on the rigid base defined by the pedestal 202. The deep trench capacitor 134 is coupled to the pedestal 202 by the adhesive 246. In particular, the first surface 248 of the deep trench capacitor 134 is coupled to the third wall 228 of the pedestal 202 such that the surface 316 of conductive material 242 (e.g., the main body) faces the deep trench capacitor 134. In other words, the adhesive 246 is positioned between the first surface 248 of the deep trench capacitor 134 and the surface 316 of conductive material 242. In some examples, the adhesive 246 is applied to the exposed surface of the pedestal 202 and then the deep trench capacitor 134 is positioned on the pedestal 202 (with the adhesive 246 therebetween). In such examples, the adhesive 246 is likely to be substantially limited in size to the area of the top surface of the pedestal. In other examples, the adhesive 246 is applied to the mounting surface of the deep trench capacitor 134 that is then placed on the pedestal 202. In such examples, the adhesive 246 may cover an area of the deep trench capacitor 134 larger than the size of the pedestal 202.

FIG. 3I illustrates the IC device 200 after deposition of the mold material 256 to fill the cavity 204. The mold material 256 is structured to secure the deep trench capacitor 134 in place in the cavity 204. The mold material 256 can be deposited into open areas of the cavity 204 and cured to secure the deep trench capacitor 134 inside the cavity 204. The rigid nature of the pedestal 202 helps support the deep trench capacitor 134 in position until the curing process is complete. Following completion of the stage of manufacture represented in FIG. 3I, the second outer layer 207 and the contact pads 258 can be deposited to achieve the final structure as shown in FIG. 2. Thereafter, further processing may follow in any suitable manner (e.g., adding build-up layers, etc.) to complete the fabrication of a package substrate that can be used as the basis for an IC package (e.g., the IC package 100 of FIG. 1).

While an example manner of fabricating the example pedestal 202 has been illustrated in FIGS. 3A-3I, one or more of the operations and/or processes illustrated in FIGS. 3A-3I may be combined, divided, re-arranged, omitted, eliminated and/or implemented in any other way. Further still, the example of FIGS. 3A-3I may include processes and/or operations in addition to, or instead of, those illustrated in FIGS. 3A-3I and/or may include more than one of any or all of the illustrated processes and/or steps.

FIG. 4 is a cross-sectional side view of another example IC device 400 constructed in accordance with teachings disclosed herein. The IC device 400 is similar to the IC device 200 of FIGS. 2 and 3A-3I. However, the IC device 400 of FIG. 4 includes multiple pedestals 202 disclosed herein. Including multiple pedestals 202 can provide for greater stability and/or a wider base or platform onto which the deep trench capacitor 134 may be positioned in place prior to the curing of the mold material 256. In the illustrated example of FIG. 4, the IC device 400 includes two pedestals 202, including a first pedestal 202A and a second pedestal 202B. However, the IC device 400 can include more than two pedestals 202 in other examples (e.g., three pedestals 202, more than three pedestals 202, etc.). The details of the parts of the IC device 200 of FIGS. 2 and 3A-3I that are common with the parts of the IC device 400 of FIG. 4 will not be described in detail again in connection with FIG. 4. Further, the same reference numbers used for structures shown in FIG. 4 will be used for similar or identical structures in FIGS. 2 and 3A-3I. Further, aspects of the example stages of manufacture represented by FIGS. 3A-3I may be adapted for use in connection with the fabrication of the IC device 400 of FIG. 4.

In some examples, the pedestals 202 are distributed in two-dimensions in a cavity 204. That is, in some examples, additional pedestals can be positioned at locations into or out of the page from the perspective shown in FIG. 4. The pedestals 202 are positioned in respective openings 232 that extend through the second outer layer 208. In particular, the first pedestal 202A is positioned in a first opening 232A and the second pedestal 202B is positioned in a second opening 232B.

A semiconductor device (e.g., the deep trench capacitor 134 of FIGS. 1, 2, and 3A-3I) is positioned on the pedestals 202 within the cavity 204. That is, the deep trench capacitor 134 is positioned on the multiple pedestals 202. Unlike what is shown in FIGS. 2 and 3A-3I, the adhesive 246 in FIG. 4 extends across the entire first surface 248 of the deep trench capacitor 134, including portions spaced apart from the pedestals 202. However, in other examples, separate portions of the adhesive 246 could be provided on the separate pedestals 202 to attach the deep trench capacitor 134 to the pedestals 202. A mold material 256 is positioned to fill the cavity 204 to secure the deep trench capacitor 134 on the pedestals 202 inside the cavity 204.

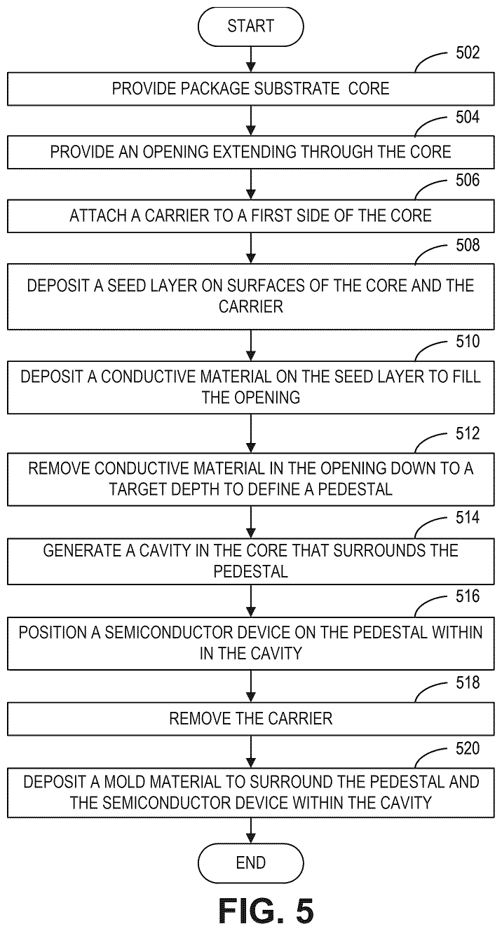

FIG. 5 is a flowchart representative of an example method of fabricating the example pedestal(s) of FIGS. 2 and/or 4 as represented by the example stages of manufacture shown in FIGS. 3A-3I. For purposes of explanation, the example process of FIG. 5 will be described primarily with reference to the IC device 200 of FIGS. 2 and 3A-3I. However, the following discussion applies similar to any other IC device disclosed herein.

At block 502, the process includes providing a package substrate core (e.g., the package substrate core 130 of FIG. 1, the package substrate core 206 of FIGS. 2 and 3A-3I, etc.). The core 130, 206 of the IC device 200 may correspond to any suitable substrate having a first surface 214 and a second surface 216 opposite the first surface 214. In some examples, the core 206 is an organic core that is lined with a first outer layer 207 on the first surface 214 of the substrate core 206 and with a second outer layer 208 on the second surface 216 of the substrate core 206. In some examples, the substrate core 206 includes the second outer layer 208 and a different outer layer 302. In some examples, the outer layers 207, 208, 302 can be omitted.

At block 504, the process includes providing an opening 304 extending through the core 206. The opening 304 can be fabricated using any suitable drilling, etching and/or cutting process. In some examples, the opening 304 is fabricating using the same or similar process to fabricate plated through-holes in the substrate core 206 and, thus, is similarly dimensioned. For example, the opening 304 has a diameter 306 that corresponds to a target diameter or width 250 of the pedestal 202 (FIGS. 2, 3H-3I).

At block 506, the process includes attaching a carrier 308 to a first surface of the core 130, 206. For example, the carrier 308 can be a temporary film coupled to an exterior surface 234 of the second outer layer 208 of the core 130, 206. The carrier 308 is a temporary carrier to facilitate development or formation of the pedestal 202 (FIGS. 2, 3H-3I).

At block 508, the process includes depositing a seed layer 240 on surfaces of the core 130, 206 and the carrier 308. In particular, the process includes depositing the a seed layer 240 on exposed surfaces of the substrate core 206 (e.g., exposed surfaces of the outer layers 208, 302 and the substrate core 206) and exposed surfaces of the carrier 308. The seed layer 240 can be deposited using suitable deposition techniques for IC devices (e.g., electroless plating).

At block 510, the process includes depositing a conductive material 242 on the seed layer 240 to fill the opening 304. In particular, the conductive material 242 is deposited to fill the opening 304. The conductive material 242 can be deposited using any suitable deposition techniques for IC devices (e.g., electrolytic plating).

At block 512, the process includes removing conductive material 242 in the opening 304 down to a target depth to define the pedestal 202. For example, the process can include etching the conductive material 242 to a target depth to define the pedestal 202. In some examples, portions of the conductive material 242 and the seed layer 240 are removed from the first surface 214 of the substrate core 206. In some examples, the different outer layer 302 is also removed. After removal of the portions of the conductive material 242 and the seed layer 240, the pedestal 202 is defined.

At block 514, the process includes generating a cavity 204 in the core 206 that surrounds the pedestal 202. In particular, the process includes providing the cavity 204 in the core 206 such that the pedestal 202 is positioned within the cavity 204. In some examples, the providing of the cavity 204 includes laser drilling the cavity 204. In some such examples, a stop point of the laser drilling is the conductive material 242 of the pedestal 202.

At block 516, the process includes positioning a semiconductor device on the pedestal 202 within the cavity 204. For example, the deep trench capacitor 134 can be coupled to the pedestal 202 by an adhesive 246. In particular, a first surface 248 of the deep trench capacitor 134 can coupled to a third wall 228 of the pedestal 202 such that a surface 316 of conductive material 242 (e.g., the main body) faces the deep trench capacitor 134. The adhesive 246 can extend across an entirety of the first surface 248 of the deep trench capacitor 134 or a portion of the first surface 248 of the deep trench capacitor 134. At block 518, the process includes removing the carrier 308.

At block 520, the process includes depositing a mold material 256 to surround the pedestal 202 and the semiconductor device 134 within the cavity 204. For example, the process can include depositing a mold material 256 to fill an open area within the cavity 204. The mold material 256 can be deposited into open areas of the cavity 204 and cured to secure the deep trench capacitor 134 inside the cavity 204.

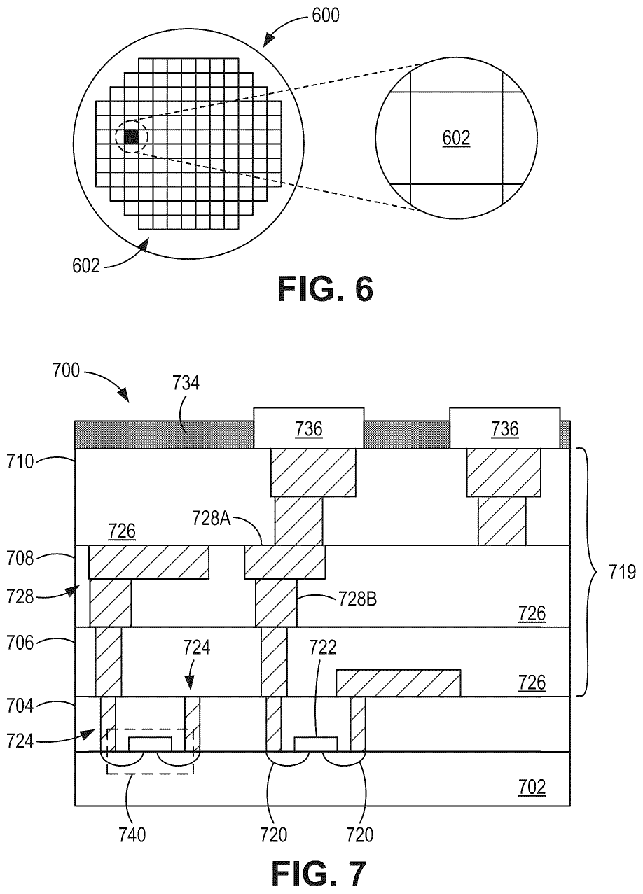

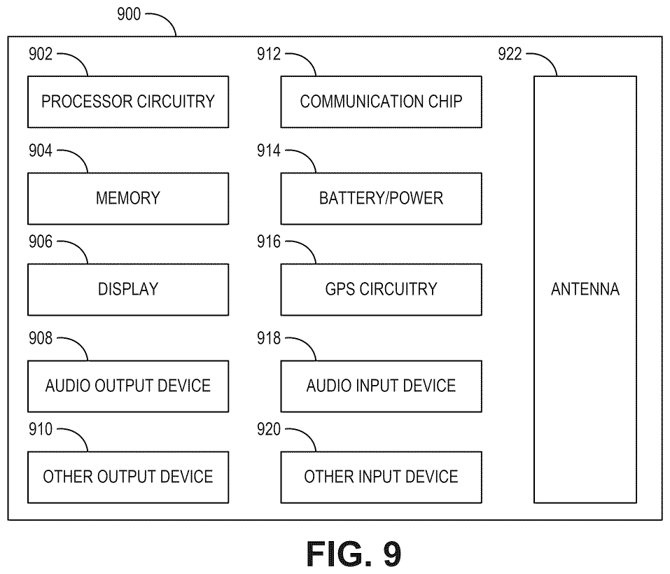

FIG. 6 is a top view of a wafer 600 and dies 602 that may be included in an IC package in accordance with any of the examples disclosed herein. The wafer 600 may be composed of semiconductor material and may include one or more dies 602 having circuitry. Each of the dies 602 may be a repeating unit of a semiconductor product. After the fabrication of the semiconductor product is complete, the wafer 600 may undergo a singulation process in which the dies 602 are separated from one another to provide discrete “chips.” The die 602 may include one or more transistors (e.g., some of the transistors 740 of FIG. 7, discussed below), supporting circuitry to route electrical signals to the transistors, passive components (e.g., traces, resistors, capacitors, inductors, and/or other circuitry), and/or any other components. In some examples, the die 602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 602. For example, a memory array formed by multiple memory circuits may be formed on a same die 602 as programmable circuitry (e.g., the processor circuitry 902 of FIG. 9) or other logic circuitry. Such memory may store information for use by the programmable circuitry.

FIG. 7 is a cross-sectional side view of an IC device 700 that may be included in an IC package whose substrate includes one or more pedestals 202 in accordance with any of the examples disclosed herein. One or more of the IC devices 700 may be included in one or more dies 602 (FIG. 6). The IC device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some examples, the die substrate 702 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an IC device 700 may be used. The die substrate 702 may be part of a singulated die (e.g., the dies 602 of FIG. 6) or a wafer (e.g., the wafer 600 of FIG. 6).

The IC device 700 may include one or more device layers 704 disposed on or above the die substrate 702. The device layer 704 may include features of one or more transistors 740 (e.g., metal oxide semiconductor field-effect transistors (MOSFETs)) formed on the die substrate 702. The device layer 704 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other examples, at least one of the metal layers that form the gate electrode may simply be a planar layer that is substantially parallel to the top surface of the die substrate 702 and does not include sidewall portions substantially perpendicular to the top surface of the die substrate 702. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of each transistor 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 720 may be formed using one or more alternate semiconductor materials such as germanium or a group III-V material or alloy. In further examples, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the IC device 700.

The interconnect structures 728 may be arranged within the interconnect layers 706-710 to route electrical signals according to a wide variety of designs (in particular, the arrangement is not limited to the particular configuration of interconnect structures 728 depicted in FIG. 7). Although a particular number of interconnect layers 706-710 is depicted in FIG. 7, examples of the present disclosure include IC devices having more or fewer interconnect layers than depicted.

In some examples, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page from the perspective of FIG. 7. The vias 728b may be arranged to route electrical signals in a direction of a plane that is substantially perpendicular to the surface of the die substrate 702 upon which the device layer 704 is formed. In some examples, the vias 728b may electrically couple lines 728a of different interconnect layers 706-710 together.

The interconnect layers 706-710 may include a dielectric material 726 disposed between the interconnect structures 728, as shown in FIG. 7. In some examples, the dielectric material 726 disposed between the interconnect structures 728 in different ones of the interconnect layers 706-710 may have different compositions; in other examples, the composition of the dielectric material 726 between different interconnect layers 706-710 may be the same.

A first interconnect layer 706 (referred to as Metal 1 or “M1”) may be formed directly on the device layer 704. In some examples, the first interconnect layer 706 may include lines 728a and/or vias 728b, as shown. The lines 728a of the first interconnect layer 706 may be coupled with contacts (e.g., the S/D contacts 724) of the device layer 704.

A second interconnect layer 708 (referred to as Metal 2 or “M2”) may be formed directly on the first interconnect layer 706. In some examples, the second interconnect layer 708 may include vias 728b to couple the lines 728a of the second interconnect layer 708 with the lines 728a of the first interconnect layer 706. Although the lines 728a and the vias 728b are structurally delineated with a line within each interconnect layer (e.g., within the second interconnect layer 708) for the sake of clarity, the lines 728a and the vias 728b may be structurally and/or materially contiguous (e.g., simultaneously filled during a dual-damascene process) in some examples.

A third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some examples, the interconnect layers that are “higher up” in the metallization stack 719 in the IC device 700 (i.e., further away from the device layer 704) may be thicker.

The IC device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to other external devices. For example, solder bonds may be formed on the one or more conductive contacts 736 to mechanically and/or electrically couple a chip including the IC device 700 with another component (e.g., a circuit board). The IC device 700 may include additional or alternate structures to route the electrical signals from the interconnect layers 706-710; for example, the conductive contacts 736 may include other analogous features (e.g., posts) that route the electrical signals to external components.

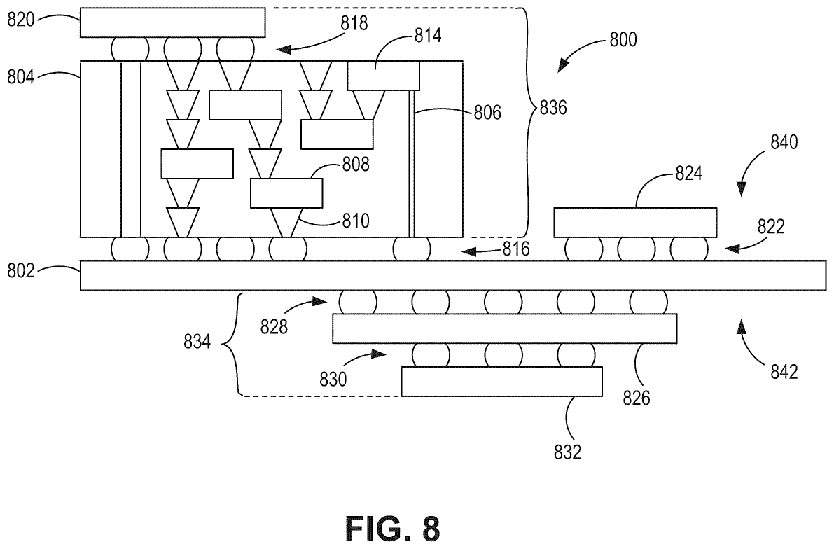

FIG. 8 is a cross-sectional side view of an IC device assembly 800 that may include the pedestal 202 disclosed herein. In some examples, the IC device assembly corresponds to the IC device 200 of FIG. 2. The IC device assembly 800 includes a number of components disposed on a circuit board 802 (which may be, for example, a motherboard). The IC device assembly 800 includes components disposed on a first face 840 of the circuit board 802 and an opposing second face 842 of the circuit board 802; generally, components may be disposed on one or both faces 840 and 842. Any of the IC packages discussed below with reference to the IC device assembly 800 may take the form of the example IC device 200 of FIG. 2.

In some examples, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other examples, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804; indeed, additional interposers may be coupled to the interposer 804. The interposer 804 may provide an intervening substrate used to bridge the circuit board 802 and the IC package 820. The IC package 820 may be or include, for example, a die (the die 602 of FIG. 6), an IC device (e.g., the IC device 700 of FIG. 7), or any other suitable component. Generally, the interposer 804 may spread a connection to a wider pitch or reroute a connection to a different connection. For example, the interposer 804 may couple the IC package 820 (e.g., a die) to a set of BGA conductive contacts of the coupling components 816 for coupling to the circuit board 802. In the example illustrated in FIG. 8, the IC package 820 and the circuit board 802 are attached to opposing sides of the interposer 804; in other examples, the IC package 820 and the circuit board 802 may be attached to a same side of the interposer 804. In some examples, three or more components may be interconnected by way of the interposer 804.

In some examples, the interposer 804 may be formed as a PCB, including multiple metal layers separated from one another by layers of dielectric material and interconnected by electrically conductive vias. In some examples, the interposer 804 may be formed of an epoxy resin, a fiberglass-reinforced epoxy resin, an epoxy resin with inorganic fillers, a ceramic material, or a polymer material such as polyimide. In some examples, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through-silicon vias (TSVs) 806. The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the examples discussed above with reference to the coupling components 816, and the IC package 824 may take the form of any of the examples discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include a first IC package 826 and a second IC package 832 coupled together by coupling components 830 such that the first IC package 826 is disposed between the circuit board 802 and the second IC package 832. The coupling components 828, 830 may take the form of any of the examples of the coupling components 816 discussed above, and the IC packages 826, 832 may take the form of any of the examples of the IC package 820 discussed above. The package-on-package structure 834 may be configured in accordance with any of the package-on-package structures known in the art.

FIG. 9 is a block diagram of an example electrical device 900. Any suitable ones of the components of the electrical device 900 may include one or more of the IC cores 206, device assemblies 800, IC devices 700, or dies 602 disclosed herein. A number of components are illustrated in FIG. 9 as included in the electrical device 900, but any one or more of these components may be omitted or duplicated, as suitable for the application. In some examples, some or all of the components included in the electrical device 900 may be attached to one or more motherboards. In some examples, some or all of these components are fabricated onto a single system-on-a-chip (SoC) die.

Additionally, in various examples, the electrical device 900 may not include one or more of the components illustrated in FIG. 9, but the electrical device 900 may include interface circuitry for coupling to the one or more components. For example, the electrical device 900 may not include a display 906, but may include display interface circuitry (e.g., a connector and driver circuitry) to which a display 906 may be coupled. In another set of examples, the electrical device 900 may not include an audio input device 918 (e.g., microphone) or an audio output device 908 (e.g., a speaker, a headset, earbuds, etc.), but may include audio input or output device interface circuitry (e.g., connectors and supporting circuitry) to which an audio input device 918 or audio output device 908 may be coupled.

The electrical device 900 may include programmable circuitry 902 (e.g., one or more processing devices). The programmable circuitry 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 900 may include a memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 904 may include memory that shares a die with the programmable circuitry 902. This memory may be used as cache memory and may include embedded dynamic random access memory (eDRAM) or spin transfer torque magnetic random access memory (STT-MRAM).

In some examples, the electrical device 900 may include a communication chip 912 (e.g., one or more communication chips). For example, the communication chip 912 may be configured for managing wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other examples. The electrical device 900 may include an antenna 922 to facilitate wireless communications and/or to receive other wireless communications (such as AM or FM radio transmissions).

In some examples, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some examples, a first communication chip 912 may be dedicated to wireless communications, and a second communication chip 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display 906 (or corresponding interface circuitry, as discussed above). The display 906 may include any visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any device that generates an audible indicator, such as speakers, headsets, or earbuds.

The electrical device 900 may include an audio input device 918 (or corresponding interface circuitry, as discussed above). The audio input device 918 may include any device that generates a signal representative of a sound, such as microphones, microphone arrays, or digital instruments (e.g., instruments having a musical instrument digital interface (MIDI) output).

The electrical device 900 may include GPS circuitry 916. The GPS circuitry 916 may be in communication with a satellite-based system and may receive a location of the electrical device 900, as known in the art.

The electrical device 900 may include any other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include any other input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example methods and apparatus for mounting semiconductor devices in cavities are disclosed herein. Further examples and combinations thereof include the following:

Example 1 includes an semiconductor package comprising a package substrate core having a cavity positioned therein, a pedestal positioned within the cavity of the core, the pedestal including a conductive material, and a capacitor disposed within the cavity, the capacitor positioned on the pedestal.

Example 2 includes the semiconductor package of example 1, wherein the pedestal includes a seed layer on lateral walls of the conductive material.

Example 3 includes the semiconductor package of example 1, wherein a depth of the cavity corresponds to a height of the pedestal and a thickness of the capacitor.

Example 4 includes the semiconductor package of example 1, further including a mold material to surround the pedestal and the capacitor in the cavity.

Example 5 includes the semiconductor package of example 1, further including an adhesive positioned between the capacitor and the pedestal.

Example 6 includes the semiconductor package of example 1, wherein the pedestal has a diameter of less than approximately 100 microns.

Example 7 includes the semiconductor package of example 1, wherein the capacitor has a width of greater than approximately 500 microns.

Example 8 includes the semiconductor package of example 1, wherein a width of the pedestal is less than one fifth a width of the capacitor.

Example 9 includes the semiconductor package of example 1, wherein the pedestal is one of a plurality of pedestals, the capacitor positioned on multiple ones of the plurality of pedestals.

Example 10 includes the semiconductor package of example 9, wherein the multiple ones of the plurality of pedestals are distributed in two-dimensions.

Example 11 includes a package substrate comprising a core, a platform positioned within a recess of the core, the platform including metal extending continuously between opposing sides of the platform, and a semiconductor component disposed within the recess, the semiconductor component disposed on the platform.

Example 12 includes the package substrate of example 11, wherein the core has a thickness of at least approximately 1 millimeter.

Example 13 includes the package substrate of example 11, wherein the metal includes copper.

Example 14 includes the package substrate of example 11, wherein the platform includes a seed layer and a main body, the seed layer defining the opposing sides of the platform, a surface of the main body facing the semiconductor component devoid of the seed layer.

Example 15 includes the package substrate of example 11, further including an adhesive material coupling the metal to the semiconductor component.

Example 16 includes the package substrate of example 11, wherein the semiconductor component includes at least one of a capacitor, a resistor, or an inductor.

Example 17 includes a method comprising, providing a core having a first side and a second side opposite the first side, providing an opening through the core, depositing an electrically conductive material within the opening, etching the electrically conductive material to a target depth to define a pedestal, providing a cavity in the core such that the pedestal is positioned within the cavity, and coupling a first surface of a capacitor structure to the pedestal, the target depth to position a second surface of the capacitor structure approximately flush with the first side of the core.

Example 18 includes the method of example 17, further including coupling a temporary substrate to the second side of the core prior to the depositing of the electrically conductive material, and removing the temporary substrate after the etching of the electrically conductive material.

Example 19 includes the method of example 17, further including depositing a mold material to fill an open area within the cavity.

Example 20 includes the method of example 17, wherein the providing of the cavity includes laser drilling the cavity, and wherein a stop point of the laser drilling is the electrically conductive material of the pedestal.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A semiconductor package comprising:
a package substrate core having a cavity positioned therein;
a pedestal positioned within the cavity of the core, the pedestal including a conductive material; and
a capacitor disposed within the cavity, the capacitor positioned on the pedestal.

2. The semiconductor package of claim 1, wherein the pedestal includes a seed layer on lateral walls of the conductive material.

3. The semiconductor package of claim 1, wherein a depth of the cavity corresponds to a height of the pedestal and a thickness of the capacitor.

4. The semiconductor package of claim 1, further including a mold material to surround the pedestal and the capacitor in the cavity.

5. The semiconductor package of claim 1, further including an adhesive positioned between the capacitor and the pedestal.

6. The semiconductor package of claim 1, wherein the pedestal has a diameter of less than approximately 100 microns.

7. The semiconductor package of claim 1, wherein the capacitor has a width of greater than approximately 500 microns.

8. The semiconductor package of claim 1, wherein a width of the pedestal is less than one fifth a width of the capacitor.

9. The semiconductor package of claim 1, wherein the pedestal is one of a plurality of pedestals, the capacitor positioned on multiple ones of the plurality of pedestals.

10. The semiconductor package of claim 9, wherein the multiple ones of the plurality of pedestals are distributed in two-dimensions.

11. A package substrate comprising:
a core;
a platform positioned within a recess of the core, the platform including metal extending continuously between opposing sides of the platform; and
a semiconductor component disposed within the recess, the semiconductor component disposed on the platform.

12. The package substrate of claim 11, wherein the core has a thickness of at least approximately 1 millimeter.

13. The package substrate of claim 11, wherein the metal includes copper.

14. The package substrate of claim 11, wherein the platform includes a seed layer and a main body, the seed layer defining the opposing sides of the platform, a surface of the main body facing the semiconductor component devoid of the seed layer.

15. The package substrate of claim 11, further including an adhesive material coupling the metal to the semiconductor component.

16. The package substrate of claim 11, wherein the semiconductor component includes at least one of a capacitor, a resistor, or an inductor.

17. A method comprising,
providing a core having a first side and a second side opposite the first side;
providing an opening through the core;
depositing an electrically conductive material within the opening;
etching the electrically conductive material to a target depth to define a pedestal;
providing a cavity in the core such that the pedestal is positioned within the cavity; and
coupling a first surface of a capacitor structure to the pedestal, the target depth to position a second surface of the capacitor structure approximately flush with the first side of the core.

18. The method of claim 17, further including:
coupling a temporary substrate to the second side of the core prior to the depositing of the electrically conductive material; and
removing the temporary substrate after the etching of the electrically conductive material.

19. The method of claim 17, further including depositing a mold material to fill an open area within the cavity.

20. The method of claim 17, wherein the providing of the cavity includes laser drilling the cavity, and wherein a stop point of the laser drilling is the electrically conductive material of the pedestal.
